(19) United States
(12) Patent Application Publication
(10) Pub. No.: US 2013/0183121 A1
(43) Pub. Date: Jul. 18, 2013

(54) VACUUM PROCESSING APPARATUS

(71) Applicants: Ryoichi Isomura, Kudamatsu (JP); Susumu Tauchi, Shunan (JP); Hideaki Kondo, Kudamatsu (JP); Michiaki Kobayashi, Kudamatsu (JP)

(72) Inventors: Ryoichi Isomura, Kudamatsu (JP); Susumu Tauchi, Shunan (JP); Hideaki Kondo, Kudamatsu (JP); Michiaki Kobayashi, Kudamatsu (JP)

(73) Assignee: Hitachi High-Technologies Corporation

(21) Appl. No.: 13/409,371

(22) Filed: Mar. 1, 2012

(30) Foreign Application Priority Data
Jan. 12, 2012 (JP) 2012-003692

(51) Int. Cl. H01L 21/677

(52) U.S. Cl. 414/217

(57) ABSTRACT

In a vacuum processing apparatus having a plurality of vacuum processing chambers at least one of which are coupled to each of a plurality of vacuum transfer chambers which are behind an atmospheric transfer chamber and have vacuum transfer robots in their interior to transfer a wafer, taking out a plurality of wafers in a cassette and transferring successively to the plurality of the vacuum processing chambers, and thereafter returning to the cassette, the wafers are controlled to be transferred to all of the vacuum processing chambers coupled to the backmost vacuum transfer chamber and thereafter a next wafer is transferred to a vacuum processing chamber which becomes possible for the next wafer to be transferred in before they are possible to be transferred out from the vacuum processing chambers coupled to the backmost vacuum transfer chamber and arranged backmost.

### BACKGROUND OF THE INVENTION

The present invention relates to a vacuum processing apparatus which is adapted to process a to-be-processed substrate such as a semiconductor wafer in a processing chamber disposed in a vacuum vessel and which includes a transfer vessel coupled to the vacuum vessel and having its interior for enabling the to-be-processed substrate to be transferred therethrough.

In the apparatus as above, especially in a vacuum processing apparatus in which a substrate such as a semiconductor wafer representing a to-be-processed sample (hereinafter, simply referred to as “a wafer”) is processed in the decompressed processing chamber disposed in a vacuum vessel, improvements of the efficiency in processing wafers of processing objects have been demanded as well as miniaturization and refinement of the processing progress. Accordingly, in recent years, a multi-chamber apparatus has been developed in which a plurality of vacuum vessels are coupled to a single apparatus to enable wafer processings in parallel in a plurality of processing chambers, thereby improving the efficiency of productivity per footprint of a clean room.

Further, in the apparatus as above having a plurality of processing chambers to carry out processing, each of the processing chambers constitutes a respective processing unit along with a means for supplying an electric field or a magnetic field thereto, an evacuation means such as an evacuation pump for evacuating the interior, a means for adjusting supply of a process gas to the interior of the processing chamber, and the like and the processing unit is detachably coupled to a transfer unit including a transfer chamber for which internal gas is adjusted and its pressure can be controlled to be lower and in which a robot arm or the like for transferring a substrate is provided, so that a wafer is transferred inside and held temporarily therein. More specifically, a side wall of a vacuum vessel in which a processing chamber to be decompressed of a respective processing unit is disposed is detachably coupled to a side wall of a vacuum transfer vessel of a transfer unit through which an unprocessed or processed wafer is transferred in its interior decompressed to the same degree, so that the interiors are configured to be capable of communication and closure.

In the above construction, the size of a whole vacuum processing apparatus is affected remarkably by sizes and arrangements of vacuum transfer vessels and vacuum processing vessels or of vacuum transfer chambers and vacuum processing chambers. For example, a vacuum transfer chamber is determined in its size to implement necessary operations with influences of the number of transfer chambers or processing chambers coupled adjacently, the number of transfer robots disposed inside to transfer wafers and the minimal radius required for their operation, and the diameter of the wafers as well. On the other hand, a vacuum processing chamber is also affected by the diameter of to-be-processed wafers, the exhaust efficiency in the processing chamber to accomplish a necessary pressure, and arrangements of instruments or the like necessary for wafer processings. Furthermore, arrangements of vacuum transfer chambers and vacuum processing chambers are also affected by the number of processing chambers needed for each processing apparatus necessary to realize the total quantity and the efficiency of production of semiconductor devices or the like the user demands at the installation site.

In addition, respective processing vessels of a vacuum processing apparatus require maintenance such as care/inspection or the like at intervals of predetermined operating times or processing sheets and an arrangement of respective instruments and respective vessels is demanded by which the maintenance as above can be performed efficiently. As a prior art for a vacuum processing apparatus in which a plurality of vacuum processing vessels and vacuum transfer vessels are arranged to be coupled with each other what is disclosed in JPA-2007-511104 has been known.

### SUMMARY OF THE INVENTION

In the prior art described above, by configuring respective processing units or transfer units to be detachable it is configured so that exchange with another unit according to details and conditions of demanded processing or requirements for maintenance and performance is possible so that the construction can be changed according to different processes while keeping them installed inside a building of the user. Further, a vacuum transfer vessel is constructed having its plane shape viewed from above made to be a polygon and each side wall corresponding to each side of the polygon is configured to be coupled detachably with a side wall of a vacuum vessel of the vacuum processing unit, a side wall of a vacuum transfer vessel of another transfer unit, or a side wall of a vessel adapted to couple them together. In the prior art, with the construction as above, by coupling vacuum transfer vessels together (an intermediate vessel to be coupled may be interposed) in the vacuum processing apparatus the degree of freedom of the number and the arrangement of vacuum processing units is increased and processings and a construction can be changed by responding to a change of specifications the user requests within a short period of time so that it is intended to keep the operation efficiency of the whole apparatus high.

The prior art described above, however, has problems with not enough consideration in the following aspect. Namely, while the arrangement and the number of permissible vacuum processing units increases by coupling the vacuum transfer vessels (irrespective of the presence/absence of intermediate vessels), sequences of transfer of wafers to vacuum processing vessels capable of optimizing the processing and the productivity efficiency of wafers according to the arrangement and the number are not taken into full consideration, resulting in the impairment of the yield of vacuum processing apparatus per footprint.

For example, when a vacuum processing apparatus includes vacuum processing units capable of performing the same processing and these vacuum processing units are coupled to different vacuum transfer vessels, in the aforementioned prior art the fact is not considered that the efficiency of processing would be impaired depending on selections of sequences of transfer/delivery of wafers which are transferred so as to be processed by them. Thus, the ability to process wafers per footprint of the vacuum processing apparatus has been impaired in the prior art.

An objective of the present invention is to provide a vacuum processing apparatus having high productivity per footprint.

The above problem is solved in a vacuum processing apparatus comprising a plurality of vacuum transfer chambers being arranged behind an atmospheric transfer chamber, being coupled mutually, and having vacuum transfer robots located in their decompressed interior to transfer a wafer; and a plurality of vacuum processing chambers, at least one of the vacuum processing chambers being coupled to each of the vacuum transfer chambers, a plurality of wafers in a cassette arranged in front of the atmospheric transfer chamber being taken out of the cassette, being transferred successively to the plurality of the vacuum processing chambers by the vacuum transfer robots to be processed, and being returned to the cassette afterwards, the transfer of the wafers is controlled such that the number of sheets of wafers processed in the backmost vacuum processing chamber becomes large.

More specifically, the transfer is adjusted in such a manner that after arbitrary wafers in a cassette are so set as to be transferred to all of the vacuum processing chambers coupled to the vacuum transfer chamber arranged backmost, the next wafer is transferred to a vacuum processing chamber which is coupled to a vacuum transfer chamber further back including the backmost vacuum transfer chamber and which becomes possible for transfer at the earliest.

Especially, it is accomplished by adjusting such that arbitrary wafers are transferred to all of the vacuum processing chambers coupled to one arranged backmost out of the plurality of the vacuum transfer chambers and consequently adjusting such that the next wafer is transferred to one of the plurality of the vacuum processing chambers possible for the next wafer to be transferred in before the arbitrary wafers become possible to be transferred out from the vacuum processing chambers coupled to the backmost vacuum transfer chamber and arranged backmost.

Other objects, features, and advantages of the invention will become apparent from the following description of the embodiments of the invention taken in conjunction with the accompanying drawings.

### BRIEF DESCRIPTION OF THE DRAWINGS

FIG. 1 is a top view for explaining a schematic construction of the whole of a vacuum processing apparatus according to an embodiment of the present invention;

FIG. 2 is a lateral cross-sectional view enlarging vacuum transfer chambers in the embodiment shown in FIG. 1;

FIG. 3 is a flow chart showing operation flow of the vacuum processing apparatus according to the embodiment shown in FIG. 1;

FIG. 4 is a top view for explaining a schematic construction of the whole of a vacuum processing apparatus according to a variation of the present invention; and

FIG. 5 is a top view for also explaining a schematic construction of the whole of a vacuum processing apparatus according to another variation of the present invention.

### DESCRIPTION OF THE EMBODIMENTS

Embodiments of a vacuum processing apparatus according to the present invention are now described in details by making reference to the accompanying drawings.

### Embodiment 1

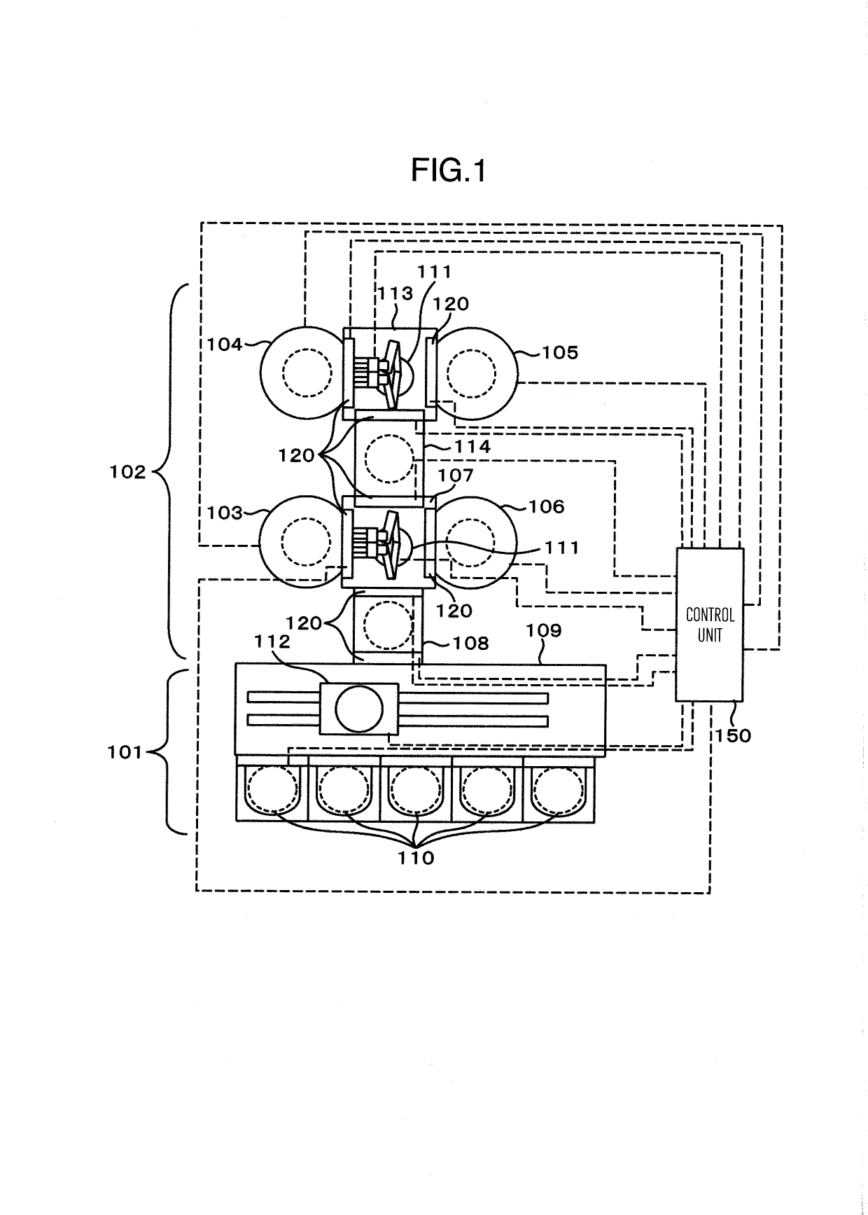

An embodiment of the present invention is now described with reference to accompanying drawings. FIG. 1 is a top view for explaining a schematic construction of the whole of a vacuum processing apparatus according to an embodiment of the present invention.

A vacuum processing apparatus 100 comprising vacuum processing chambers according to an embodiment of the present invention shown in FIG. 1 is roughly constructed of an atmosphere-side block 101 and a vacuum-side block 102. The atmosphere-side block 101 is a part in which a sample in the form of a substrate such as a semiconductor wafer to be processed is transferred, positioned for accommodation, or the like in the atmospheric pressure and the vacuum-side block 102 is a block in which the substrate-like sample such as a wafer is transferred in a pressure decompressed from the atmospheric pressure and processing is preformed in a predetermined vacuum processing chamber. Then, between a spot of the vacuum-side block 102 for execution of the aforementioned transfer/processing of the vacuum-side block 102 and the atmosphere-side block 101, a portion is arranged which couples them and in which the pressure is raised/lowered between the atmospheric pressure and the vacuum pressure while a sample is held inside.

The atmosphere-side block 101 includes a cabinet 109 of a substantially rectangular shape internally equipped with an atmospheric transfer robot 112 and a plurality of cassette stands 110 which are attached on the front surface side of the cabinet 109 and on which cassettes storing substrate-like samples such as semiconductor wafers to be processed in processing or cleaning (hereinafter, referred to as wafers) are mounted.

The vacuum-side block 102 includes a single or a plurality of lock chambers 108 which are arranged between a set of the first vacuum transfer chamber 107 and the second vacuum transfer chamber 113 and the atmosphere-side block 101 and the pressure of which is changed between the atmospheric pressure and the vacuum pressure while wafers to be transferred between the atmospheric side and the vacuum side are stored therein. The lock chamber 108 is a vacuum vessel having its internal space adjustable to the aforementioned pressure and there are arranged at the spot of coupling a passage through which the wafer passes and is transferred and a valve 120 which opens and closes air-tightly the passage to section the atmospheric side and the vacuum side hermetically. Also equipped in the internal space is a storage part capable of storing and holding a plurality of wafers by mutually spacing them vertically, so that it is sectioned off hermetically with the wafers stored by closing the valve 120.

Although only one lock chamber 108 as viewed from above is illustrated in FIG. 1, a plurality of (two in the case of the example of FIG. 1) lock chambers each of which is dimensioned equally or close enough to be considered equal are arranged overlapped in the vertical direction in the present embodiment. It should be noted that a plurality of lock chambers 108 are hereinafter described merely as a lock chamber 108 unless a notice is given to the contrary. As seen above, the vacuum-side block 102 is a block in which vessels capable of maintaining pressure of a high degree of vacuum are coupled and the whole interior is a space maintained as being decompressed.

The first vacuum transfer chamber 107 and the second vacuum transfer chamber 113 are units each of which contains a vacuum vessel having a plan shape of a substantially rectangular shape and are two units which have so little differences in structure that they can be considered as substantially the same. Between the side walls corresponding to the opposing faces of the first vacuum transfer chamber 107 and the second vacuum transfer chamber 113 a vacuum transfer intermediate chamber 114 is arranged and couple them together.

The vacuum transfer intermediate chamber 114 is a vacuum vessel capable of its interior decompressed to an equivalent degree of vacuum to other vacuum transfer chambers or vacuum processing chambers so that vacuum transfer chambers are coupled together and their interiors are in communication to each other. Arranged between vacuum transfer chambers and it are valves 120 adapted to open and close to section passages inside of which a wafer is transferred in communication to the interior chambers and by closing the valves 120 the vacuum transfer intermediate chamber and the vacuum transfer chambers can be sealed hermetically.

Also equipped in the interior of the vacuum transfer intermediate chamber 114 is a storage part for mounting and holding horizontally a plurality of wafers by mutually spacing their surfaces, having a function of a relay chamber to temporarily store a wafer when the wafer is transferred between the first and second vacuum transfer chambers 107 and 113. Namely, the wafer transferred in by a vacuum transfer robot 111 in one vacuum transfer chamber and then mounted on the storage part is transferred out by a vacuum transfer robot 111 in the other vacuum transfer chamber and then transferred to a vacuum processing chamber or a lock chamber coupled to the vacuum transfer chamber.

To describe a structure of the vacuum transfer intermediate chamber 114 in the present embodiment, like the arrangement configuration of the lock chamber 108, two chambers are arranged in an overlapping position in the vertical direction. More specifically, the vacuum transfer intermediate chamber 114 comprises a detachable partition plate, not shown, inside a vacuum vessel constituting a space for storing wafers internally to section it up and down and movement of gas and particles between the two sectioned rooms is mitigated.

In other words, the vacuum transfer intermediate chamber 114 is a station in which wafers ready to undergo processing in the respective vacuum processing chambers or wafers having undergone processing therein are stored and there is a possibility that a state occurs in which while an unprocessed wafer scheduled to be applied with processing in one of these vacuum processing chambers is on hold in the storage space in the vacuum transfer intermediate chamber 114 a processed wafer having undergone processing in another vacuum processing chamber is transferred into the storage space or a state occurs in which while a wafer processed in the second vacuum processing chamber 104 or the third vacuum processing chamber 105 is waiting for transfer to any lock chamber 108 in the storage space an unprocessed wafer to undergo processing in any one of the vacuum processing chambers is transferred in the space. In the circumstance as above with the configuration described above, such a problem that the unprocessed wafer and the processed wafer are present simultaneously in the vacuum transfer intermediate chamber 114 to cause gas or product residing around the latter to affect the former adversely is suppressed.

Especially, in the present embodiment, in the respective top and bottom storage parts of the two storage space in the vacuum transfer intermediate chamber 114, two or more wafers are configured to be storable with their respective upper and lower surfaces spaced apart from each other and within each an unprocessed wafer is stored above and a processed wafer is stored below. With this structure, even in each of the storage spaces, gas and product residing around the processed wafer can be suppressed from adversely affecting the unprocessed wafer.

In each of the top and bottom storage parts, a wafer-mounting part is arranged having a shelf structure for storing and holding two or more wafers; these mounting parts comprise flanges extending along two side wall faces opposing (in the left-to-right direction in FIG. 1) inside of the vacuum transfer intermediate chamber 114 constituting the storage part and with a length sufficient to hold the wafers with edge parts of the outer circumference of the wafer mounted thereon in the horizontal direction (in the direction normal to the drawing plane in FIG. 1) towards the side wall surface opposing to them and arranged with a predetermined space in the vertical direction, wherein each of the flanges on the side wall faces corresponding to the respective side wall face sides is at the same height and arranged in a slightly smaller distance than the diameter of the wafers, thus providing a shelf structure (slot) while opening a wide space at the central portion of the wafer or the storage part.

The number of the slots of the mounting part constituting such a plurality of steps is so determined as the number of sheets of wafers which are temporarily stored inside the mounting part in the course of transfer among the second vacuum processing chamber 104, the third vacuum processing chamber 105, or the lock chamber 108, which are destination spots, during operation of the vacuum processing apparatus 100. In other words, the number of steps of the mounting part comprises the number of steps which is sufficient to store at least one for each of unprocessed and processed wafers of processing objects.

Further, in any lock chamber 108 in the present embodiment a stage on which the wafer is mounted is arranged in a room for storing a wafer internally and on the top surface of the stage at least one or more of protrusion parts of convex shapes are arranged with their height positions fixed on their upper ends of which a wafer is mounted so that the upper ends and the bottom surface of the wafer are in contact with each other. Such protrusion parts are structured so that a gap may develop between the upper ends of the convex shapes and the top surface of the stage when the wafer is mounted on the protrusion parts.

By supporting the wafer stored in the lock chamber 108 while leaving the gap as above, gas can be supplied to the interior of the storage chamber while the two gate valves arranged at the front and back ends (the ends in the up-and-down direction in FIG. 1) of respective lock chambers 108 are closed to section the interior hermetically so that the temperature of the wafer can be made close to a desired range. Especially, when the wafer after being processed in a vacuum processing chamber is at a high temperature, by efficiently cooling the post-processed wafer in the lock chamber 108 while being transferred to the atmosphere-side block 101, occurrences of failures such as cracking or damage in the course of transfer inside the atmosphere-side block 101 can be mitigated.

As to the first vacuum transfer chamber 107, its two faces not connected with the lock chamber 108 or the vacuum transfer intermediate chamber 114 are connected with the first vacuum processing chamber 103 and the fourth vacuum processing chamber 106 inside of which is decompressed for a wafer to be transferred in and processed. In this embodiment, each of the first to fourth vacuum processing chambers represents a whole unit including a means of generating an electric field and a magnetic field configured to include a vacuum vessel and a means of exhausting including a vacuum pump for evacuating an internal space of vessel to be decompressed and in the internal processing chamber an etching process, an ashing process, or another process to be applied to a semiconductor wafer is applied. Also connected to each of the first to fourth vacuum processing chambers is a piping through which a process gas supplied in accordance with a process to be carried out flows.

To the first vacuum transfer chamber 107 two vacuum processing chambers are configured to be able to couple with. Although in the present embodiment connected to the first vacuum transfer chamber 107 are the first vacuum processing chamber 103 and the fourth vacuum processing chamber 106, either one of them only may be connected. The second vacuum transfer chamber 113 is so structured to be able to couple with three vacuum processing chambers but in the present embodiment up to two vacuum processing chambers 104 and 105 are coupled.

Each of the vacuum processing chambers in this embodiment comprises a vacuum vessel and a processing chamber of a cylindrical shape in its interior. At an central portion of the inside of the processing chamber, a sample stage of a cylindrical shape is arranged with its central axis aligned with the axis of the cylinder and on the top surface of the sample stage a film made of a dielectric having a film-like electrode arranged inside is disposed by a method such as thermal spraying or bonding a sintered member, for example, thus configuring a mounting surface adapted to mount a wafer and in a shape of a circle or a circular shape approximating enough to be recognized to be to an extent. The wafer carried on the mounting surface is held thereon by electrostatic force generated between the film and the wafer as a result of application of DC electric power to the electrode arranged internally of the film.

In addition, in the mounting surface described above a plurality of through-holes are disposed in which a plurality of pins moving in the vertical direction are stored inside. These pins move from lower positions, where they are stored in the through-holes, to upper positions so as to protrude to above the mounting surface and then a wafer is mounted on their tip ends; or in the condition that the wafer in mounted on the mounting surface, the pins move up from the inside of the through-holes to make their tip ends come into contact with the rear surface of the wafer and further moves upward so that the wafer can be lifted up to a position above the mounting surface with a gap formed.

With the pins which are able to move up and down equipped as above and penetrating an arm tip of a vacuum transfer robot 111 into a space below the tip ends of the pins and lifting the arm or by moving the pins down an operation of delivering a wafer to the arm tip can be performed; by moving the pins up from the interiors of the through-holes or by moving the arm down with the pins protruding above the mounting surface after the arm tip carrying a wafer moves over the mounting surface to a position at which the center of the wafer coincides with the center of the mounting surface as viewed from above an operation of delivering the wafer to the sample stage side including the upper ends of the pins can be performed.

The first vacuum transfer chamber 107 and the second vacuum transfer chamber 113 are configured so that their interiors are constructed as transfer chambers and in the first vacuum transfer chamber 107 a vacuum transfer robot 111 which transfers a wafer in vacuum between the lock chamber 108 and any of the first vacuum processing chamber 103, the fourth vacuum processing chamber 106, and the vacuum transfer intermediate chamber 114 is disposed at a center portion of the internal space. Similarly, in the second vacuum transfer chamber 113, a vacuum transfer robot 111 is disposed at a center portion of its interior to transfer a wafer with any of the second vacuum processing chamber 104, the third vacuum processing chamber 105, and the vacuum transfer intermediate chamber 114.

The vacuum transfer robot 111, on an arm of which a wafer is mounted, in the first vacuum transfer chamber 107 transferring in or out of a wafer is performed with any of the wafer stage arranged in the first vacuum processing chamber 103 or the fourth vacuum processing chamber 106 or the lock chamber 108 or the vacuum transfer intermediate chamber 114. In between the first vacuum processing chamber 103 and the fourth vacuum processing chamber 106, the lock chamber 108, the vacuum transfer intermediate chamber 114, the transfer chambers of the first vacuum transfer chamber 107 and the second vacuum transfer chamber 113, passages which can be closed hermetically or opened respectively by valves 120 are arranged and a wafer is transferred through these passages while it is mounted and held on the arm tip end of the vacuum transfer robot 111.

In the present embodiment with the above construction, transfer of a wafer by the vacuum transfer robot 111 disposed in the interior of either of the first vacuum transfer chamber 107 and the second vacuum transfer chamber 113 is carried out between any one of the plurality of the vacuum processing chambers and the lock chamber 108 or the vacuum transfer intermediate chamber 114 or between the lock chamber 108 and the vacuum transfer intermediate chamber 114. In a configuration where three or more vacuum transfer chambers are coupled and other vacuum transfer intermediate chambers are arranged in addition to the vacuum transfer intermediate chamber 114, a wafer is transferred also between the vacuum transfer intermediate chambers. Among them, transfer operation including transfer of a wafer with a vacuum processing chamber, that is, the ones including transfer operation performing transfer-in of an unprocessed wafer or transfer-out of a processed wafer in association with any one of the vacuum processing chambers consume a time longer than that required for the other operations.

Given as a reason for the above is that any one of the vacuum processing chambers in this embodiment has in the sample stage the pins which move in the up-and-down directions to perform transfer of a wafer with the vacuum transfer robot and much time is required for operating the pins and, besides, the transfer is needed to be with precise positioning of the position of the wafer with respect to the mounting surface on the sample stage so that the centers are aligned and operations of transfer and handing over cannot be performed at excessively high speeds.

On the other hand, since in the vacuum transfer intermediate chamber 114 and the lock chamber 108 the portions for holding a wafer internally do not move in the vertical direction and it can be done only by moving the vacuum transfer robot 111 in the vertical direction and, besides, as compared to the case of transfer for mounting on the sample stage in the vacuum processing chamber, high accuracy is not required for positioning the arm of the vacuum transfer robot 111, the time necessary for operation of the transfer in which the vacuum transfer robot 111 between the vacuum transfer intermediate chambers 114 and between one of them and the lock chamber 108 receives a wafer from one to transfer out and transfers in to another to mount it therein can be shortened.

In the present embodiment, a wafer mounted on a wafer support portion at an arm tip end of the atmospheric transfer robot 112 is adhered and held to the wafer support portion by an adhering device disposed on a wafer contact surface of the wafer support portion and occurrence of drift of the wafer on the support portion by operation of the arm can be prevented. Particularly, it comprises a configuration in which a wafer can be adhered onto the contact surface by reducing the pressure with sucking surrounding gas through a plurality of openings arranged in the contact surface of the wafer support portion.

On the other hand, instead of performing the adhesion based on sucking, convex members, protrusions, or pins to suppress positional drifts by becoming in contact with a wafer are arranged on the wafer support portion at the arm tip end onto which a wafer is mounted by the vacuum transfer robot 111 to suppress drifts of the wafer due to operation of the arm. Furthermore, in order to suppress positional drifts as above, the speeds or the rates of the speed changes (accelerations) of the arm operation are suppressed and, consequently, longer time is necessary for the vacuum transfer robot 111 to transfer a wafer over the same distance and the efficiency of transfer is decreased in the vacuum-side block 102.

In the present embodiment, hereinafter, an instance is described in which under the condition that the transfer time in the vacuum-side block 102 is longer than that in the atmosphere-side block 101 the time to transfer a sample on a transfer path routing the vacuum transfer chamber, the intermediate chamber, and the vacuum processing chamber constituting the vacuum-side block 102 can be reduced to improve the efficiency of processings. In addition, the time to perform processing on a wafer in each of the vacuum processing chambers is substantially equal to or less than that of transfer and the time of transfer has a larger influence, particularly a dominating influence upon the number of sheets of wafers to be processed per unit time throughout the vacuum processing apparatus 100.

Next, operation of performing processing on a wafer in the vacuum processing apparatus 100 as above is described.

Processings of a plurality of wafers stored in a cassette mounted on any one of the cassette stands 110 initiate as a command is received from a not shown control device, which controls operation of the vacuum processing apparatus 100, connected to the vacuum processing apparatus 100 by any communication means or a command is received from a control device or the like of a production line in which the vacuum processing apparatus 100 is installed. The atmospheric transfer robot 112 which receives a command from the control device takes a particular wafer inside a cassette out of it and transfers the taken-out wafer to the lock chamber 108.

In the lock chamber 108, in which the wafer is transferred and stored, with the transferred wafer being stored, the valve 120 is closed and sealed to be decompressed to a predetermined pressure. Thereafter, in the lock chamber 108, the valve 120 on the side facing the first vacuum transfer chamber 107 is opened to bring the lock chamber 108 and the first vacuum transfer chamber 107 into communication with each other.

The vacuum transfer robot 111 extends its arm into the lock chamber 108 to receive the wafer in the lock chamber 108 onto the wafer support portion at its arm tip end and transfers out into the first vacuum transfer chamber 107. Further, the vacuum transfer robot 111 transfers the wafer mounted on its arm in to any of the first vacuum processing chamber 103, the fourth vacuum processing chamber 106, and the vacuum transfer intermediate chamber 114 which are connected to the first vacuum transfer chamber 107 along a path of transfer designated in advance by the control device at the time when the wafer is taken out of the cassette. For example, the wafer transferred to the vacuum transfer intermediate chamber 114 is subsequently transferred from the vacuum transfer intermediate chamber 114 to the second vacuum transfer chamber 113 by the vacuum transfer robot 111 provided in the second vacuum transfer chamber 113 and transferred in to either one of the second vacuum processing chamber 104 and the third vacuum processing chamber 105 which is a destination of the aforementioned predetermined transfer path.

In the present embodiment, the valves 120 are opened/closed exclusively. Namely, the wafer transferred to the vacuum transfer intermediate chamber 114 is sealed in the vacuum transfer intermediate chamber 114 with the valve 120 for opening/closing with the first vacuum transfer chamber 107 being closed. Subsequently, the valve 120 to open/close between the vacuum transfer intermediate chamber 114 and the second vacuum transfer chamber 113 is opened and the vacuum transfer robot 111 provided in the second vacuum transfer chamber 113 is extended so as to transfer the wafer into the second vacuum transfer chamber 113. The vacuum transfer robot 111 transfers the wafer mounted on its arm to either one of the second vacuum processing chamber 104 and the third vacuum processing chamber 105 which is determined in advance at the time when the wafer is taken out of the cassette.

After the wafer is transferred to either one of the second vacuum processing chambers 104 and the third vacuum processing chamber 105, the valve 120 for opening/closing between the vacuum processing chamber into which the wafer is transferred and the second vacuum transfer chamber 113 connected thereto is closed to seal off the vacuum processing chamber. Thereafter, gas for processing is introduced to the processing chamber and the inside of the vacuum processing chamber is adjusted to a pressure suitable for the processing. An electric field or a magnetic field is supplied to the vacuum processing chamber so that the process gas is excited to generate plasma in the processing chamber and the wafer is processed.

The valve 120 to open/close between the one vacuum processing chamber into which the wafer is transferred to be processed and the second vacuum transfer chamber 113 coupled thereto is opened in response to a command from a not shown control device with other valves 120 capable of opening/closing the space to which the vacuum transfer chamber is inclusively connected in communication being closed. For example, before the valve 120 which sections between the one vacuum processing chamber and the vacuum transfer chamber connected thereto is opened, the control device not shown commands an operation of performing closure or confirmation of closure of the valves adapted to open/close gates (passages the interior through which the wafer is transferred) arranged on the other three side walls of the vacuum processing chamber; after completion of the confirmation, the valve 120 hermitically sealing the one vacuum processing chamber is opened.

When completion of the processing of the wafer is detected, after it is confirmed that the valve 120 between each of the other vacuum processing chambers and the second vacuum transfer chamber 113 is closed and that hermetic seal between them is established, subsequently, the valve 120 for opening/closing between the one vacuum processing chamber and the second vacuum transfer chamber 113 connected thereto is opened and the vacuum transfer robot 111 transfers the processed wafer to its interior and transfers the wafer to the lock chamber 108 along a transfer path reverse to that for transferring the wafer in to the processing chamber. At that moment, the valve 120 which sections the first vacuum transfer chamber 107 and the second vacuum transfer chamber 113 may be kept opened when it is confirmed that all of the vacuum processing chambers coupled thereto is hermetically sealed by the valves 120.

When the wafer is transferred to the lock chamber 108, the valve 120 for opening/closing the passage through which the lock chamber 108 and the first vacuum transfer chamber 107 can be brought into communication to each other is closed to hermetically seal the first vacuum transfer chamber 107 and the pressure in the lock chamber 108 is raised to the atmospheric pressure. Thereafter, the valve 120 which sections with the inside of the cabinet 109 is opened to place the interior of the lock chamber 108 in communication to that of the cabinet 109 and the atmospheric transfer robot 112 transfers the wafer from the lock chamber 108 to the original cassette, thereby returning the wafer to the original position in the cassette.

In the present embodiment, the operation of individual parts and elements constituting the vacuum processing apparatus 100 such as the individual vacuum processing chambers, the first and the second vacuum transfer chambers 107 and 113, the vacuum transfer robots 111, the atmospheric transfer robot 112, the lock chamber 108, and the gate valves 120 and the operation of sensors disposed in them are controlled by a control unit 150 having a computing unit and a memory device equipped inside. The control unit 150 is connected to the above-mentioned individual parts by communication means so as to be able to communicate with them to receive outputs from the sensors via the communication means, to calculate command signals with its computing unit based on the received information, and to transmit the command signals to the individual parts via the communication means so as to control their operations. Coupling between the communication means and the control unit 150 is carried out through one or more interfaces disposed in the control unit 150.

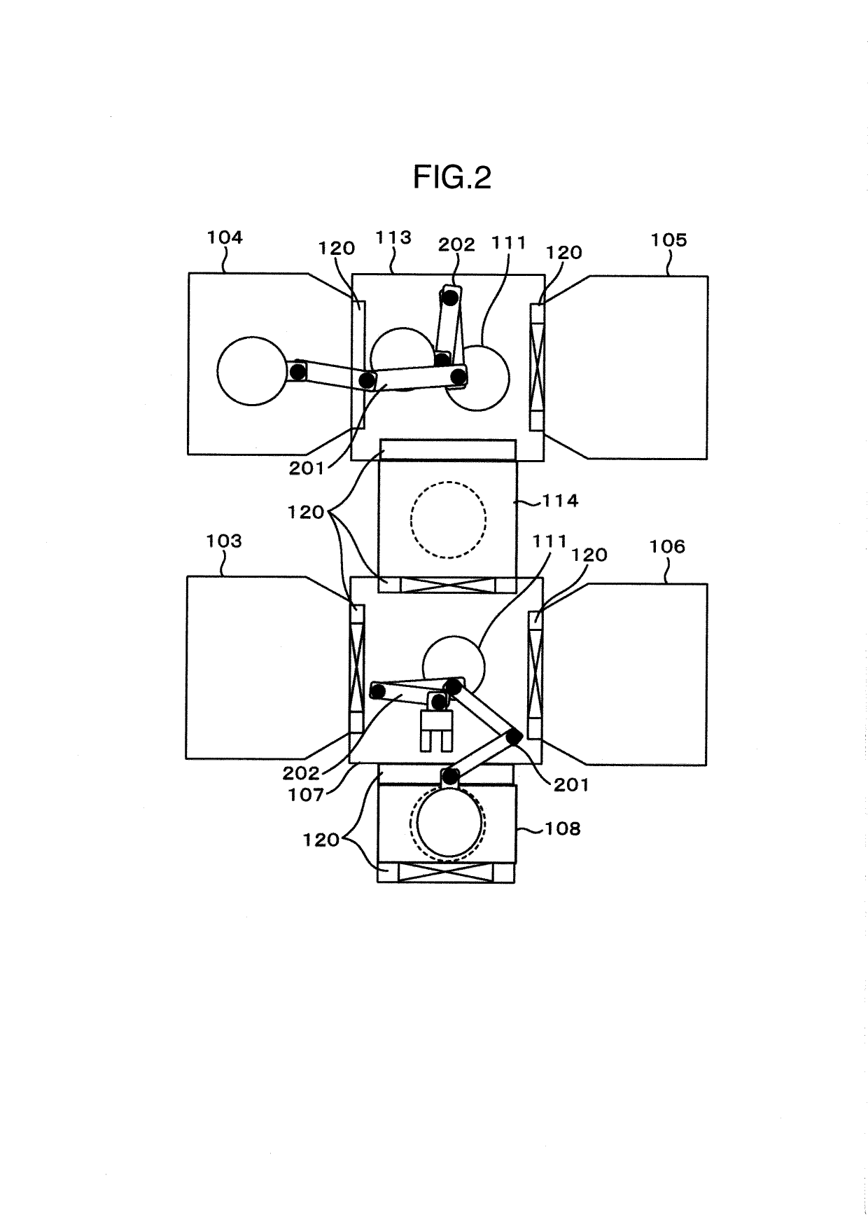

FIG. 2 shows an enlarged view of the first vacuum transfer chamber 107 and the second vacuum transfer chamber 113 described in connection with FIG. 1. The vacuum transfer robot 111 has the first arm 201 and the second arm 202 which are adapted to transfer wafers. In this embodiment the two arms are provided but the number of arms may be set as a plural number, for example, three or four.

In each of the arms, a plurality of links (at least three in the figure) of beam shapes are mutually coupled at their ends by joints so as to be able to rotate about the axes of joints and by adjusting the speed and the angle (the amount of rotation) of rotation of each joint the arm conducts operation of extending and folding (contracting) so that a wafer mounted and held on the top surface of a hand portion disposed at one end of a tip link portion of a plurality of links can be moved in a certain direction. Also, one end of the link closest to the root out of the plurality of the links is coupled to the center portion of the first vacuum transfer chamber 107 or the second vacuum transfer chamber 113 so as to be able to rotate about the rotation axis in the up-and-down direction (in the direction perpendicular to the sheet of the drawing in the figure). Further, the height of the link coupled to the root can be raised or lowered in the axial direction of the rotation axis with the result that in each of the arms the height position of a hand at the tip end or of a wafer mounted thereon can be changed.

Further, by carrying out the aforementioned rotation about the rotation axis at the center portion while a position corresponding to the center of the tip portion or of a wafer mounted thereon is made closest to the rotation axis by contracting each of the first and second arms the vacuum transfer robot 111 moves to such opposable positions with respect to the four gates arranged on the side walls of the vessel of the vacuum transfer chamber that the hand at the tip portion with the wafer mounted thereon can pass through the gate by extending and contracting them. Also, the first and the second arms are so structured that while a wafer is mounted on the hand portion arranged at tip end of one arm the other arm can stretch/shrink.

With such operation, from a condition that one of the two arms is shrunk while holding an unprocessed wafer, the other arm is shrunk while holding no wafer, and they are arranged at a position where the rotational operation described above is possible, the other arm is stretched to penetrate through a gate into the inside of any one of the first vacuum processing chamber 103, the second vacuum processing chamber 104, the third vacuum processing chamber 105, the fourth vacuum processing chamber 106, and the vacuum transfer intermediate chamber 114 to receive a processed wafer disposed in the chamber and shrunk to transfer the wafer out of the chamber and, thereafter, one arm is sequentially stretched to transfer the unprocessed wafer into the interior of the chamber and to hand off, thereby ensuring that an exchange operation can be carried out. Alternatively, from a condition that one of the two arms is shrunk while mounting a processed wafer and the other arm is shrunk at the position where the rotational operation described above is possible while holding no wafer, the other arm is stretched to penetrate through a gate into the inside of either the vacuum transfer intermediate chamber 114 or the lock chamber 108 to receive onto the hand an unprocessed wafer disposed in the chamber and transfer it out of the chamber and, thereafter, one arm is sequentially stretched to transfer the processed wafer held on the hand at the tip end in to the chamber to arrange it and, subsequently, to retreat, thus performing an exchange operation.

In the present embodiment, except that the transfer operation by the atmospheric transfer robot 112 is started from the condition that no wafer is present in the vacuum-side block 102 of the vacuum processing apparatus 100 or that at the time of starting the maintenance, at the end of lot, or the like all the wafers in the vacuum-side block 102 are transferred out, the aforementioned exchange operation is carried out with the cassettes, the lock chamber 108, the vacuum transfer intermediate chamber 114, and the individual vacuum processing chambers in transfer of wafers by the vacuum transfer robot 111 and the atmospheric transfer robot 112. By the operation as above, time required for operating the wafer transfer can be shortened, thereby achieving improvements in the time to process a plurality of sheets of wafers, or the efficiency of operation and throughput of the vacuum processing apparatus 100.

The vacuum transfer robot 111 comprises a configuration in which the first and the second arms perform operations of the rotational direction and of the height direction concurrently in the same directions, respectively, and only the stretch/shrink operations of the arms can be done independently. Also, regarding arm stretch/shrink operations, at the time when one arm starts shrink operation after stretching, the other arm can conduct stretch operation concurrently. With this construction, when the vacuum transfer robot 111 shown in FIG. 2 holds an unprocessed wafer on one arm, a processed wafer held in any transfer destination and the unprocessed wafer which the vacuum transfer robot 111 holds can be exchanged without the rotation operation and the efficiency and capability of the wafer transfer can be enhanced.

In a vacuum processing apparatus which has an apparatus configuration as shown in FIG. 1, an operation method for improving the production efficiency of the apparatus by controlling a sequence of wafer transfer/processing is now described.

In this embodiment, it is preferable that the processing time/condition is the same for all wafers held in cassettes provided on the cassette stand 110. An explanation is given below on the assumption that processing conditions are the same for wafers in the cassettes provided on the cassette holders 110 (hereinafter referred to as an alternate processing).

A description is given provided that at an initial condition no wafers undergoing processing/transfer in the atmosphere-side block 101 and the vacuum-side block 102 exist. In the vacuum processing apparatus 100 according to the present embodiment shown in FIG. 1, cassettes which hold a plurality of wafers internally are mounted on the four cassette stands 110 from the left, respectively. It is determined in advance that all wafers are to be subjected to the alternate processing. Mounted on the right-most cassette stand 110 is no cassette or a cassette internally holding a plurality of dummy wafers to be used for cleaning between processings of wafers.

In respect of the wafers held in these cassettes, when the wafers are being taken out of the cassettes, particular vacuum processing chambers in which the wafers are processed are determined in advance by the control device not shown and they are transferred to the vacuum processing chambers with the respective vacuum transfer robots.

Here, the control unit 150 of the vacuum processing apparatus 100 first transmits a command to transfer any one of the wafers stored inside of any one of the four cassettes to one of the vacuum processing chambers. A signal of the command at that moment includes, along with information of one of the vacuum processing chambers which is a target station for the wafer to be transferred, processing conditions at the processing chamber and information of a route through which the wafer is handed over and transferred such as which one of the storage parts of the lock chamber 108 and the vacuum transfer intermediate chamber 114 and which one of the two arms of the vacuum transfer robots 111. Further, such the command is transmitted under a condition where processing of a specific cluster (hereinafter called a lot) of a plurality of wafers of the same constitution (film structures, species, processing conditions, or the like) among wafers stored in the cassettes installed in the vacuum processing apparatus 100 is not yet started.

Especially, regarding a setting of the transfer operation transmitted as a signal of a command, it is preferable that information of the transfer path and the processing conditions is set by the control unit and stored in a memory device not shown in respect of all wafers belonging to the lot before the cassettes are mounted and the transfer operation by the atmospheric transfer robot 112 is started. In the present embodiment a command is transmitted such that the first wafer 1 transferred out by the atmospheric transfer robot 112 from any one of the plurality of the cassettes mounted on the cassette stands 110 which belongs to the lot is to be transferred to the first vacuum transfer chamber 107 through any lock chamber 108 so as to be processed in the first vacuum processing chamber 103.

While the wafer 1 is being transferred, the atmospheric transfer robot 112 takes a wafer 2 to be processed next out of any one of the cassettes based on a command signal from the control unit 150 and transfers it to any lock chamber 108. In respect of the wafer 2, in the same as above, any vacuum processing chamber representing a transfer destination and the transfer route are set in advance by the control unit 150 and in this embodiment it is commanded to be transferred to the second vacuum processing chamber 104.

After the wafer 1 is transferred into the interior of the first vacuum processing chamber 103, the valve 120 arranged between the first vacuum processing chamber 103 and the first vacuum transfer chamber 107 is closed, and it is detected by not shown sensors that all of the valves 120 for opening/closing the four gates in communication to the first vacuum transfer chamber 107 and the valve 120 for opening/closing the gate on the atmospheric side of any lock chamber 108 into which the wafer 2 is stored are closed hermetically, the valve 120 for opening/closing the gate at the vacuum side end part (the upper end part in the drawing) of the any lock chamber 108 is opened and the vacuum transfer robot 111 receives the wafer 2 from the interior of the lock chamber 108 to transfer it out of the chamber with one of the two arms based on a command signal from the control unit. At that time, when the other arm holds a processed wafer, the other arm is stretched to penetrate the hand part holding the wafer into the lock chamber 108 so as to hand off the processed wafer onto the protrusion parts on the stage inside.

After the opened valve 120 is closed, the valve 120 in the first vacuum transfer chamber for opening/closing of the vacuum transfer intermediate chamber 114 is opened and an unprocessed wafer is mounted in a slot of the upper section in any storage part in the vacuum transfer intermediate chamber 114 by stretching one arm. At this moment, communication between the vacuum transfer chambers may be cut by closing the valve 120 for opening/closing between the vacuum transfer intermediate chamber 114 and the second vacuum transfer chamber 113.

Subsequently, after the valve 120 of the vacuum transfer intermediate chamber 114 on the side of the first vacuum transfer chamber 107 is closed, the wafer 2 is transferred to the second vacuum processing chamber 104 by the vacuum transfer robot 111 similarly to the wafer 1. At that time, opening/closing of the valves 120 to open/close communication among the second vacuum transfer chamber 113, the vacuum transfer intermediate chamber 114, the second vacuum processing chamber 104, and the third vacuum processing chamber 105 is exclusively carried out so as not to establish communication to the vacuum-side block 102 other than these chambers.

In respect of wafers 3 and 4 to be processed next which are stored in any one of the cassettes and belong to the same lot, before starting the operation of transferring out from the cassettes by the atmospheric transfer robot 112, it is set by the control unit that they are to be transferred to the third vacuum processing chamber 105 and the fourth vacuum processing chamber 106, respectively, to be processed therein and command signals are transmitted, followed by initiation of operation.

Regarding a wafer 5 in the lot to be processed subsequently being transferred out of a cassette so as to be transferred to a transfer destination, if all of the wafers 1 to 4 are to be processed for the film structure of the same constitution at the same conditions, the processing of the wafer 1 in the first vacuum processing chamber 103 is to be completed first and becomes transferable. The control unit 150 sets a target vacuum processing chamber which is a transfer destination for the wafer 5 to the first vacuum processing chamber 103 before the transfer of the wafer 5 begins and transmits a command signal for transfer.

Namely, in the first vacuum processing chamber 103, the wafer 5 is exchanged with the wafer 1 through exchange operation of the vacuum transfer robot 111 disposed in the first vacuum transfer chamber 107 to be transferred into the first vacuum processing chamber 103 and processed therein after the processing of the wafer 1 is completed. On the other hand, in the event that the processing is not completed at a time expected in advance or the unprocessed wafer 5 does not become transferable due to some cause such as irregularity or operation failure of the first vacuum processing chamber 103, the transfer of wafer 5 is on standby until the second vacuum processing chamber 104 becomes possible to be transferred to and until the completion of the processing of the wafer 1 in the first vacuum processing chamber 103.

Such the standby may be done as storing the wafer 5 in the lock chamber 108 after taking the wafer 5 out of any one of the cassettes and transferring to the interior of any lock chamber 108 or, alternatively, as holding it on one arm after taking it out of the lock chamber 108 by the vacuum transfer robot 111. The time limit for the standby to continue corresponds to a time point at which the difference between a time when it becomes to a state that the processing of the wafer 2 in the second vacuum processing chamber 104 ends and the processed wafer 2 becomes transferable and a time when the wafer 2 is held by the vacuum transfer robot 111 in the second vacuum transfer chamber 113 and becomes transferable into the second vacuum processing chamber 104 (exchange operation) becomes zero or minimal.

In the vacuum processing apparatus 100 according to the present embodiment described above, an example is shown in which wafers are transferred out one by one from any of four cassettes mounted on the plurality of the cassette stands 110. An equivalent operation can proceed in which a cassette from which wafers are transferred out is limited to any of the four cassettes and, when the cassette become empty of unprocessed wafers, wafers in another cassette are transferred out again one by one, thus performing an operation of sequentially processing per each of a plurality of cassettes.

Further, it may be set in such a manner that before starting operation of transferring the wafer 1 or the wafer 2 the correspondence (allocation) between each of the four cassettes and any one of the first vacuum processing chamber 103, the second vacuum processing chamber 104, the third vacuum processing chamber 105, and the fourth vacuum processing chamber 106, which perform processing of the wafers stored in each cassette is set up so that the wafers are transferred one by one from each of the four cassettes to the corresponding vacuum processing chamber and are processed therein. In this case, in the event that any of the vacuum processing chambers does not become possible to be transferred to at a time presumed in advance as described above, such operation is not carried out that a target of the transfer destination is changed to another vacuum processing chamber and the unprocessed wafer is transferred to the changed vacuum processing chamber to apply processing to the wafer.

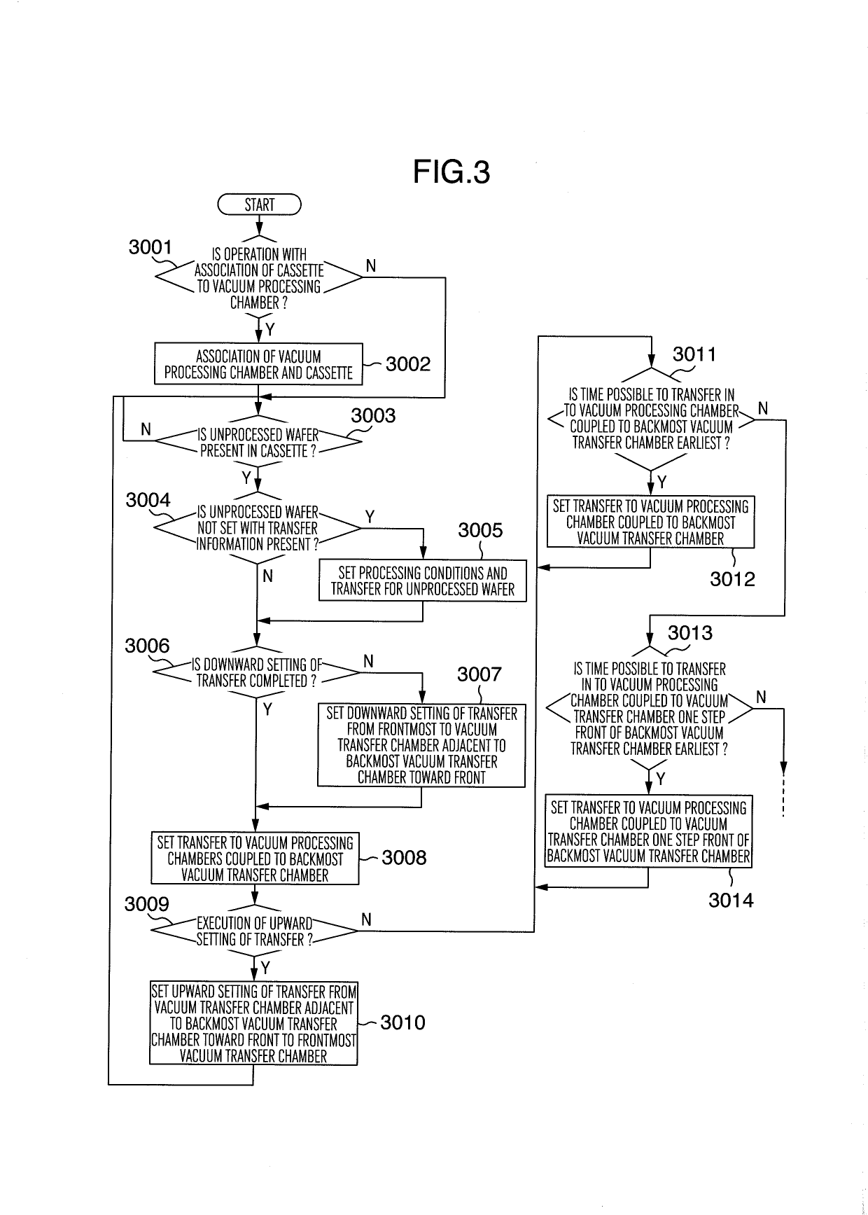

The transfer operation the vacuum processing apparatus 100 of the present embodiment performs as described above is carried out along a flow of operation shown in FIG. 3. While in the vacuum processing apparatus 100 according to this embodiment two vacuum processing chambers are coupled to each of the first vacuum transfer chamber 107 and the second vacuum transfer chamber 113, the transfer operation is not limited to that performed with the above construction of the present embodiment and even in a constitution in which three or more vacuum transfer chambers are coupled through vacuum transfer intermediate chambers, respectively, and each is coupled with one or more vacuum processing chambers the transfer operation can be carried out in a similar manner.

Incidentally, FIG. 3 shows a flowchart illustrating the flow of operation of the vacuum processing apparatus according to the present embodiment shown in FIG. 1. Especially, shown is the flow of operation of setting the vacuum processing chambers for processing each of a plurality of unprocessed wafers stored in the plurality of the cassettes mounted on the plurality of the respective cassette stands 110 and their sequences or setting the routes of transfer to the vacuum processing chambers. After the plurality of the wafers stored in the plurality of the cassettes are transferred to the vacuum processing chambers of the transfer destinations and processed according to the transfer sequences or the transfer routes set in accordance with the flow in the figure, they are returned to the original positions in the original cassettes.

Besides, it is assumed that the operation shown in the present figure is carried out when the operation by the vacuum processing apparatus 100 shown in FIG. 1 for processing wafers is performed properly according to command signals from the control unit 150 and a plurality of sheets of wafers belonging to arbitrary lots are processed within the expected time period (referred to as a steady state hereinafter).

In the present figure, upon starting the operation of the vacuum processing apparatus 100, the control unit 150 for adjusting the operations of the individual parts of the vacuum processing apparatus 100 determines correspondence of the cassettes and the vacuum processing chambers, that is, whether the operation is to be allocated to cassettes or the allocation is not fixed by obtaining information in advance including a command from a higher-ranking control unit (for example, a precedence host computer which is adapted to adjust and command the overall operation of a plurality of wafer processing apparatuses in a building where the vacuum processing apparatus 100 is installed) or a command from a user (Step 3001). When one cassette is allocated to one vacuum processing chamber in the operation, it proceeds to Step 3002; when the operation is executed without allocation, it proceeds to Step 3003.

When the operation is with allocation of a cassette to a processing chamber, each of the cassettes and the plurality of the vacuum processing chambers are associated with each other in Step 3002. In the present embodiment, each of the four cassette stands 110 is associated with and allocated to each of the four vacuum processing chambers; it means each of the cassettes transferred in the building in which the vacuum processing apparatus 100 is installed and mounted on the respective cassette stands 110 and each of the vacuum processing chambers are associated with each other and it is technically identical to making correspondence of a single cassette to a single vacuum processing chamber while the plurality of the cassettes are mounted on the cassette stands 110, respectively.

Next, in Step 3003, the control unit detects whether an unprocessed wafer is present or not in each cassette mounted on the cassette stand 110. In case no unprocessed wafers are present in the cassette, the wafers in the cassette have been processed and it is on standby until a cassette storing unprocessed wafers is transferred to the vacuum processing apparatus 100 and exchanged with the cassette storing processed wafers so that unprocessed wafers become possible to be transferred out from the cassette.

Next, when it is detected that unprocessed wafers are stored in the cassettes on the cassette stands 110, the control unit detects the presence/absence of settings of the transfers of the unprocessed wafers (Step 3004). If settings of transfers of all unprocessed wafers stored in the cassettes are done, the processing operation is initiated by transferring the wafers at a time set either by the control unit or the precedence control unit such as a host computer or based on a command from a user.

If, in Step 3004 described above, the presence of an unprocessed wafer not determined for transfer settings is detected, the control unit commands setting of transfer to a vacuum processing chamber corresponding to (allocated to) a cassette storing this wafer and setting of conditions of processing in this vacuum processing chamber (Step 3005). This command includes the vacuum processing chamber being the transfer destination in respect of this wafer and conditions for processing of this wafer in this vacuum processing chamber.

On the other hand, if the absence of any unprocessed wafer not subjected to the above setting is detected, processings of unprocessed wafers are started in accordance with a command from the control unit. At least one sheet of wafers for which the processing conditions or transfer conditions are set are started to be transferred at a time set by the control unit and are then processed.

In the present embodiment, the control unit sets transfer conditions of wafers so that the transfer of a wafer in a cassette allocated to either one of the first vacuum processing chamber 103 and the fourth vacuum processing chamber 106, which are connected to the first vacuum transfer chamber 107 closest to the cabinet 109, that is, arranged at most toward front of the vacuum processing apparatus 100 and coupled to the lock chamber 108, is started to be transferred. The conditions for the transfer include a schedule of the transfer which includes the sequence of the transfer of the unprocessed wafer with respect to other unprocessed wafers, a time when the transfer is actually started or it passes or stagnates on the route and the transfer route (vacuum processing chambers, vacuum transfer chambers, vacuum transfer intermediate chambers, lock chambers, and the like).

On the other hand, when there are no unprocessed wafers in the cassettes allocated to the two vacuum processing chambers coupled to the first vacuum transfer chamber 107 or when it is detected that neither of the vacuum processing chambers becomes possible to transfer out a wafer disposed therein at a time when the unprocessed wafer in the lock chamber 108 of the vacuum-side block 102 becomes possible to be transferred out into the interior of the first vacuum transfer chamber 107, the control unit sets the schedule of transfer of a wafer so that the transfer of the wafer in a cassette allocated to any one of the vacuum processing chambers coupled to the vacuum transfer chamber coupled and arranged behind the first vacuum transfer chamber 107 is initiated.

As described above, the vacuum processing apparatus 100 according to the present embodiment sets conditions for transferring unprocessed wafers so that an unprocessed wafer in a cassette allocated to any one of the vacuum processing chambers coupled to the respective vacuum transfer chambers from the frontmost vacuum transfer chamber to the vacuum transfer chamber adjacent to the backmost vacuum transfer chamber (one step toward front of the backmost) are transferred sequentially (downward setting). Such downward setting is commenced in the sequence described above (Step 3007) after it is detected whether the downward setting to the vacuum processing chambers coupled to the vacuum processing chamber which is one step toward front of the backmost is completed (Step 3006). In the present embodiment, the schedule for transferring an unprocessed wafer in the cassette allocated to the first vacuum processing chamber 103 is set such that a wafer is transferred in the downward setting to the first vacuum processing chamber 103 coupled to the first vacuum transfer chamber 107.

Next, the control unit sets schedules for transferring unprocessed wafers such that the unprocessed wafers are transferred to all the vacuum processing chambers coupled to the backmost vacuum transfer chamber. Namely, the schedules are set for transferring unprocessed wafers in the respective cassettes allocated to the respective vacuum processing chambers coupled to the backmost vacuum transfer chamber (Step 3008). In this embodiment, the schedules for transferring wafers are set so that the wafers stored in a cassette associated with (allocated to) the second vacuum transfer chamber 113 are transferred to the second vacuum processing chamber 104 and the third vacuum processing chamber 105 coupled to the vacuum transfer chamber.

Subsequently, in order for wafers to be transferred to the vacuum processing chambers for which unprocessed wafers are not transferred in the downward setting described above out of the vacuum processing chambers coupled to the vacuum transfer chamber which is one step toward front of the backmost vacuum transfer chamber, the schedules for transferring unprocessed wafers in the cassettes allocated to the vacuum processing chambers are set. In the present embodiment, in order to transfer to the second vacuum processing chamber 104 and the third vacuum processing chamber 105 each one of the unprocessed wafers stored inside the two respective cassettes allocated thereto, the schedules for transferring the wafers are set.

Thereafter, transfers of unprocessed wafers are set so that to the vacuum processing chambers coupled to the vacuum transfer chamber which is one more step toward front of (adjacent to) the vacuum transfer chamber which in turn is one step toward front of the backmost vacuum transfer chamber unprocessed wafers in the cassettes allocated to the vacuum processing chambers are transferred; in a way that unprocessed wafers are transferred to the vacuum processing chambers to which no wafers are transferred in the downward setting in Step 3007 out of the vacuum transfer chambers coupled to the respective vacuum transfer chambers up to the first vacuum transfer chamber 107 arranged frontmost of the vacuum processing apparatus 100 (upward setting) the transfers of these unprocessed wafers in the cassettes allocated to the vacuum processing chambers are set (Step 3010). In the present embodiment, in a way that transferred to the fourth vacuum processing chamber 106 coupled to the first vacuum transfer chamber 107 is an unprocessed wafer in the cassette allocated thereto, the schedule for transferring the wafer is set.

In the above operation with allocation at the steady state, until wafers are transferred in to all of the vacuum processing chambers connected to the backmost vacuum transfer chamber after completion of the downward setting to the vacuum processing chambers coupled to the vacuum transfer chamber one step toward front to the backmost vacuum transfer chamber, no wafers shall be transferred to the vacuum processing chambers connected to the front vacuum transfer chambers. In other words, once in the above operation the operation of the vacuum processing apparatus 100 is carried out in accordance with the transfer schedules set for unprocessed wafers stored in respective cassettes, when the number of wafers to be processed is greater than the number of the vacuum transfer chambers constituting the vacuum processing apparatus 100 and wafers are transferred to all the vacuum processing chambers connected to the vacuum transfer chambers in the back so that no more transfers of wafers are possible, the conditions for wafer transfers are set such that wafers are transferred to the vacuum processing chambers which are connected to the vacuum transfer chambers in the front and to which no wafers are transferred yet and the processing is executed.

On the other hand, when in Step 3001 operation without allocation in which the cassettes and the vacuum processing chambers are not associated with each other as operation of the vacuum processing apparatus 100, as in the case of the operation with allocation, it is detected in Step 3003 whether any wafer not set with transfer information is present among unprocessed wafers stored in the cassettes mounted on the cassette stands 110. When the presence of such a wafer is not detected, either all wafers in the cassettes have been processed or the conditions for transfers are set to all wafers; it is on standby until a cassette storing unprocessed wafers for which the schedules for transfers are not set is transferred to the vacuum processing apparatus 100 and is exchanged with a cassette storing processed wafers so that it becomes possible to transfer a wafer out from the cassette storing the unprocessed wafers.

In the present embodiment, it subsequently proceeds to Step 3006 and the settings of transfers with downward setting in Step 3007 described above is carried out. Namely, in the way that unprocessed wafers in any of the cassettes mounted on the cassette stands 110 are transferred one at a time to any one of the vacuum processing chambers which are coupled to the respective vacuum transfer chambers from the frontmost vacuum transfer chamber coupled to the lock chamber 108 (the first vacuum transfer chamber 107) to the vacuum transfer chamber adjacent by one step toward front to the backmost vacuum transfer chamber the schedules for transferring the wafers are set. Further it proceeds to Step 3008 and, schedules for transferring unprocessed wafers are set such that the wafers are transferred to all the vacuum processing chambers coupled to the backmost vacuum transfer chamber.

In the present embodiment, the schedules for transferring two unprocessed wafers are set such that the unprocessed wafers are transferred sequentially to the second vacuum processing chamber 104 and the third vacuum processing chamber 105, respectively, coupled to the second vacuum transfer chamber. In the vacuum processing apparatus 100 according to the present embodiment, it is decided whether the transfer with the upward setting in Step 3010 is executed. In case the operation without allocation is carried out and the operation with the upward setting is not conducted, it proceeds to Step 3011.

Thereafter, the schedule for transfer is set such that the processings of wafers in the vacuum processing chambers coupled to the backmost vacuum transfer chamber are carried out preferentially. In Step 3011, when a vacuum processing chamber presumed to become possible for an unprocessed wafer to be transferred in at the earliest after transfer of an unprocessed wafer to the vacuum processing chamber coupled to the backmost vacuum transfer chamber is set is coupled to the backmost vacuum transfer chamber, the control unit sets a schedule for transferring an unprocessed wafer such that the unprocessed wafer is transferred to the vacuum processing chamber.

In other words, in respect of an unprocessed wafer to be transferred next after an arbitrary unprocessed wafer the transfer schedule of which is so set as to be transferred to the vacuum processing chamber coupled to the backmost vacuum processing chamber, the control unit 150 in the present embodiment sets operations of individual parts of the vacuum processing apparatus 100 such as the vacuum transfer robot 111 so that an unprocessed wafer is transferred to the backmost vacuum processing chamber which becomes possible to be transferred to at the earliest from a specific time point calculated in accordance with the transfer conditions.

In the present embodiment, the control unit detects a vacuum processing chamber for which transfer of a wafer becomes possible at the earliest by the time when the unprocessed wafer to be transferred next is taken out of a cassette and transferred so that it becomes possible for the wafer to be transferred in to the interior of the vacuum transfer chamber adjacent toward front to the backmost vacuum transfer chamber (Step 3011) and, when it is one of those coupled to the backmost vacuum transfer chamber, it sets a schedule for transfer so that the unprocessed wafer is transferred to the vacuum processing chamber (Step 3012).

More specifically, when it is detected that either one of the second vacuum processing chamber 104 and the third vacuum processing chambers 105 which are coupled to the second vacuum transfer chamber 113 becomes possible for a wafer to be transferred in earlier than either one of the first vacuum processing chamber 103 and the fourth vacuum processing chamber 106 at the time when the vacuum side valve 120 of the lock chamber 108 in the present embodiment is opened so that an unprocessed wafer stored inside and decompressed becomes transferable into the interior of the first vacuum transfer chamber 107, the unprocessed wafer is transferred to the interior of the vacuum transfer intermediate chamber 114 by the vacuum transfer robot 111 to be transferred in to the vacuum processing chamber which becomes possible to be transferred to earlier.

If a vacuum processing chamber other than the vacuum processing chambers coupled to the backmost vacuum transfer chamber is determined to become capable for a wafer to be transferred in at the earliest, a vacuum processing chamber to which a wafer becomes possible to be transferred at the earliest is detected among the vacuum processing chambers coupled to one or more vacuum transfer chambers coupled to the front side of the backmost vacuum transfer chamber and a schedule for transferring the wafer is set such that the unprocessed wafer is transferred thereto. Namely, in Step 3013 the control unit detects a vacuum processing chamber which becomes capable for a wafer to be transferred in at the earliest by the time when the unprocessed wafer to be transferred next as described above is taken out of a cassette and transferred so that it becomes possible for the wafer to be transferred in to the interior of the vacuum transfer chamber adjacent by one more step toward front to the vacuum transfer chamber adjoining toward front the backmost vacuum transfer chamber. The schedule for transferring the unprocessed wafer is set such that it is transferred to the vacuum processing chamber when the vacuum processing chamber is a vacuum processing chamber coupled to a vacuum processing chamber coupled to a vacuum transfer chamber adjacent toward front to the backmost vacuum transfer chamber and, otherwise, to a vacuum processing chamber which becomes possible for a wafer to be transferred in at the earliest among vacuum transfer chambers coupled to one of the vacuum transfer chambers toward front including the adjacent (one more step toward front) vacuum transfer chamber (Step 3014).

More specifically, when it is detected that either one of the first vacuum processing chamber 103 and the fourth vacuum processing chamber 106 is capable for an unprocessed wafer to be transferred in earlier than either one of the second vacuum processing chamber 104 and the third vacuum processing chamber 105 which are coupled to the second vacuum transfer chamber 113 at the time when the vacuum side valve 120 of the lock chamber 108 is opened so that an unprocessed wafer stored inside and decompressed becomes transferable to the interior of the first vacuum transfer chamber 107, the unprocessed wafer is transferred by the vacuum transfer robot 111 in the first vacuum transfer chamber 107 from the interior of the lock chamber 108 to the vacuum transfer chamber.

In the case of a vacuum processing apparatus provided with three or more vacuum transfer chambers, there may exist a vacuum processing chamber which is rendered possible for an unprocessed wafer to be transferred in earlier than the vacuum processing chamber coupled to the vacuum transfer chamber one more step toward front of the aforementioned backmost vacuum transfer chamber. In such a case, the control unit applies the aforementioned flow of setting the transfer schedule to the vacuum transfer chamber arranged further toward front and the vacuum processing chambers coupled thereto and sets a schedule for transferring a next unprocessed wafer.

In the vacuum processing apparatus 100 according to the present embodiment to perform operation without allocation as above the control unit sets the transfers of unprocessed wafers such that the number of sheets of the wafers which are processed in vacuum processing chambers coupled and arranged toward the back in the vacuum processing apparatus 100 becomes larger among the wafers included in a lot to operate the vacuum processing apparatus. Namely, it is set so that unprocessed wafers are transferred to vacuum processing chambers which finish the processings earlier prior to the start of processings of the unprocessed wafers among vacuum processing chambers coupled to vacuum transfer chambers toward the back.

More specifically, in respect of an arbitrary unprocessed wafer, the vacuum processing apparatus 100 detects based on commands from the control unit with two subjects of a respective vacuum transfer chamber and another vacuum transfer chamber adjacent thereto toward front from the backmost to the frontmost one out of the vacuum processing chambers coupled to the two vacuum transfer chambers which becomes possible for a wafer to be transferred at the earliest at the time when the unprocessed wafer becomes possible to be transferred into the vacuum transfer chamber toward front between them; when it is the vacuum processing chamber coupled to the back side vacuum transfer chamber, the control unit sets a schedule for transfer of the wafer such that the unprocessed wafer is transferred to this vacuum processing chamber so as to be processed therein. When a vacuum processing chamber coupled to the toward front vacuum transfer chamber becomes capable of being transferred in earlier, the aforementioned detection of a vacuum processing chamber which becomes possible to be transferred in is repeated with the subjects of the toward front vacuum transfer chamber and a vacuum transfer chamber one more step toward front.

In the vacuum processing apparatus 100, by performing the transfer and the processing of a wafer according to the setting of the transfer as above, when the wafer processing from taking out of a cassette to returning to the original cassette after being processed is carried out successively for the cluster (lot) of a plurality of wafers stored in the cassette, the time required for processing the lot is shortened and, as a result, the number of processed sheets per unit time (throughput) is improved. Further, when the operation with allocation is carried out, the wafers stored in the inside of each of a plurality of the cassettes and each of the plurality of the vacuum processing chambers are associated with each other to make it easy to grasp characteristics and histories of the processings for each cassette and, by presuming the characteristics of the processing in each of the processing chambers identical or close with the respective cassettes, processings to be performed after the processings for each lot carried out by the vacuum processing apparatus 100 can be adjusted lot by lot and, as a result, the yield and the reproducibility of the processings are improved. Also, since the correspondence among the wafers, the lots, and the vacuum processing chambers is clear, even when a failure is detected in respect of an arbitrary wafer, irregularity of a whole of a particular lot can be predicted from the wafer in which the failure occurs and the causes can also be detected easily.

Incidentally, even in the operation with allocation, operation may be executed in which the transfer to vacuum processing chambers toward the back is preferred by proceeding to Step 3011 in place of the transfer with the upward setting in Step 3010 after completion of the downward setting operation in Step 3008. Furthermore, in the vacuum processing apparatus 100 adapted to perform the above operation, the stations arranged on transfer paths of the wafers in which the wafers are held and stagnate temporarily, that is the atmospheric transfer robot 112, the lock chamber 108, the vacuum transfer robot 111 in the first vacuum transfer chamber 107, the vacuum transfer intermediate chamber 114, and the vacuum transfer robot 111 in the second vacuum transfer chamber 113 are each adjusted for their operations by the control unit so that they perform the operation of transferring a wafer transferred from the station of the upstream side to the wake side of the route within a shortest period of time as much as possible, which is a so-called first-in-first-out operation.

After a cassette is transferred and mounted on the cassette stand 110, the control unit carries out immediately setting for transfers of unprocessed wafers stored in the cassette. Especially, the control unit calculates with an calculator the time associated with the operation of wafer transfer before starting the transfer of the wafers using software memorized in a memory device such as RAM disposed therein.

At that time, since times of operations associated with transfer such as the times to start and to end the operations of the vacuum transfer robots 111 in transfer of each wafer and the times to start and to end the open/closure of the valves 120 differ depending on the settings of the routes and the sequences of transfer, the above calculations should be conducted for a plurality of schedules in which conditions for transfer including the routes and the sequences of the transfer and the like are different so that conditions for transfer to minimize the time from taking the wafer out of the cassette and returning it back and, besides, to minimize the time from taking out an initial wafer of the lot representing a cluster of a plurality of wafers to returning the last one sheet back can be selected and set.

By executing the control as above, it becomes possible to distribute transfer loads to be imposed on the respective vacuum transfer robots arranged in the vacuum transfer chambers and to improve the production efficiency of the overall apparatus.

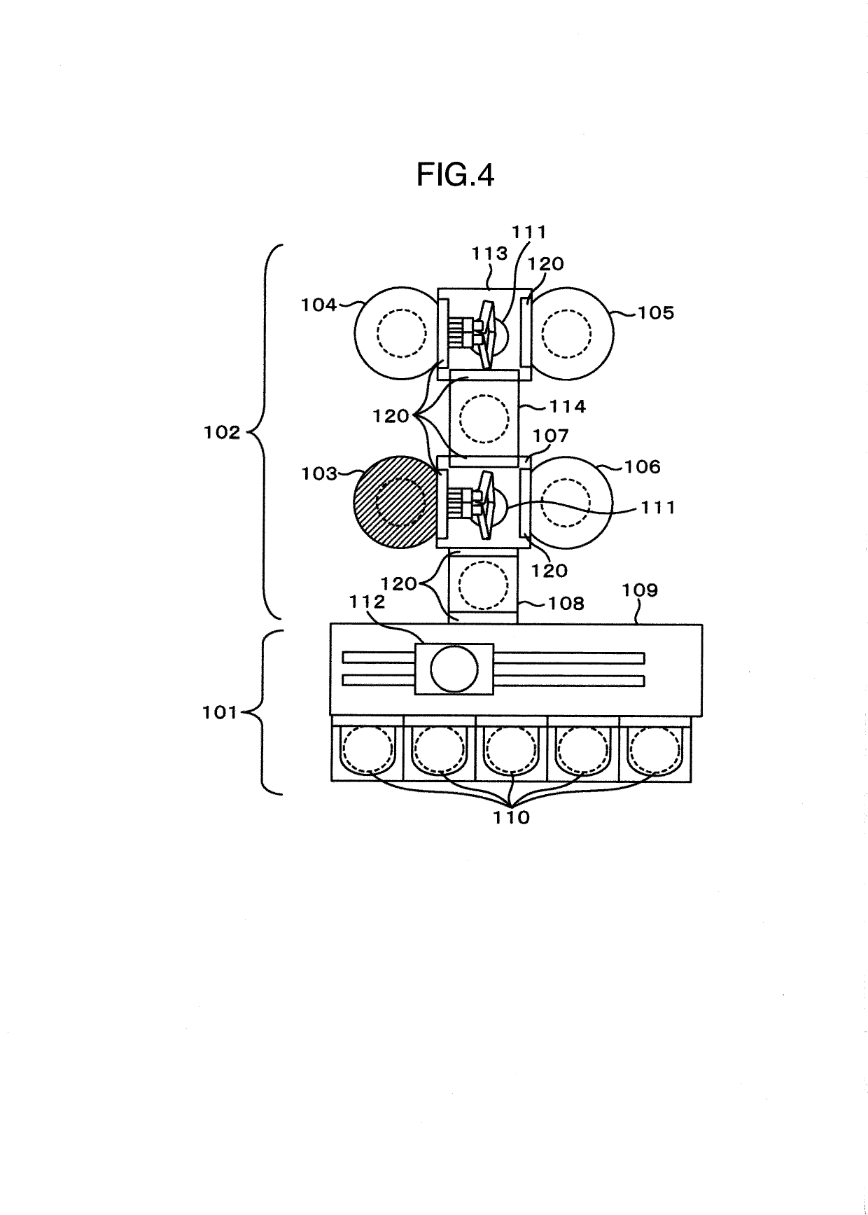

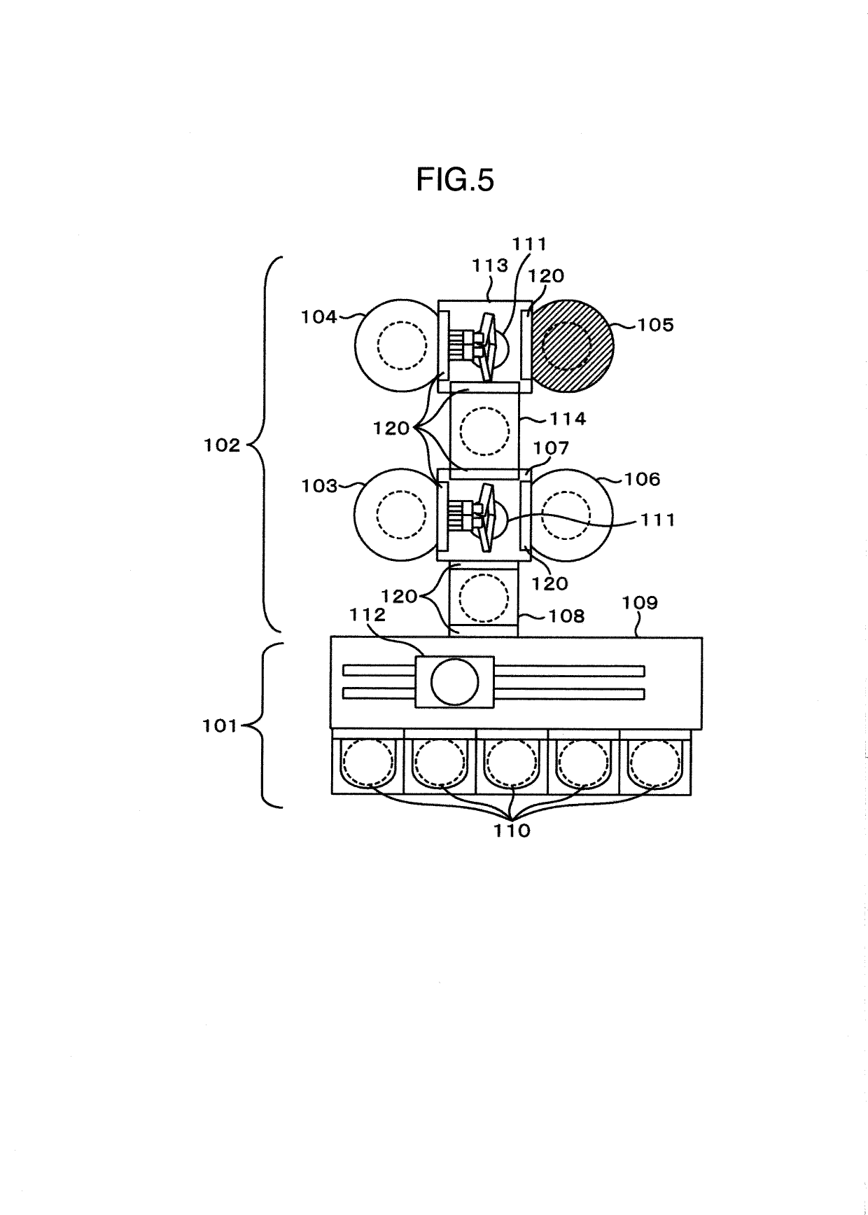

Next, the states are described in each of which after the processings have proceeded to some extent an abnormal state is detected in some of the vacuum processing chambers and processings are halted in the vacuum processing chamber by making reference to FIG. 4 and FIG. 5.

In FIG. 4 is a top view schematically illustrating a state in which a failure occurs in a particular vacuum processing chamber in the vacuum processing apparatus according to the embodiment shown in FIG. 1. Similar to the embodiment shown in FIG. 1, wafers are processed through the alternate processing. The vacuum processing apparatus shown in FIG. 4 has a configuration in which each of two vacuum processing chambers is arranged in parallel in the front-to-back direction and two vacuum transfer chambers mutually coupled are coupled in the left-to-right (left-to-right in the drawing) direction as viewed from the front similarly to the case of FIG. 1.

In the present example, a state in which the first vacuum processing chamber 103 is stopped due to some failure at the time when the processings of a plurality of wafers are completed in the operation with allocation is shown by hatching the first vacuum processing chamber 103. Upon occurrence of the failure in the first vacuum processing chamber 103 the control unit 150 controls the operation by transmitting commands to the respective parts so that wafers on the way of transfer are returned once to the original storing positions in the original cassettes and no new transfers for processings of unprocessed wafers should be started. Further, similarly to the above, wafers being processed in any of the second processing chamber 104, the third processing chamber 105, and the fourth processing chamber 106 are returned to their original positions in the original cassettes after their processings have been completed.

Further, the control unit controls the operation in such a manner that the wafer in the first vacuum processing chamber 103 in which a failure occurs is also transferred out from the processing chamber and returned to the original position in the original cassette, if possible. When it is determined that transferring out and returning the wafer in the first vacuum processing chamber 103 is difficult, the valve 120 for opening/closing the gate for bringing the first vacuum processing chamber 103 and the first vacuum transfer chamber 107 into communication to each other is closed hermetically to section the interior of the first vacuum processing chamber 103 hermetically.

After wafers on their ways of transfer and wafers in processing are returned to the cassettes with the condition as above, no sheets of wafers have been transferred in to the three vacuum processing chambers and, while the first vacuum processing chamber 103 is a state of being stopped, the other vacuum processing chambers are ready for starting processings of wafers. Thereafter, operation is resumed using the other sections in the vacuum-side block 102 and the atmosphere-side block 101 to continue the processings of the wafers in the cassettes and the maintenance/inspection work of the interior of the first vacuum processing chamber 103 is carried out as necessary.

The schedule for transfer is set again from the state above in such a manner that a wafer to be transferred first among the unprocessed wafers in the cassettes designated by the control unit is transferred to the fourth vacuum processing chamber 106 in the transfer operation with the downward setting. The condition for transfer is set such that an unprocessed wafer to be taken out of the cassette subsequently is transferred to either one of the vacuum processing chambers connected to the second vacuum transfer chamber 113 according to the operation in Step 3008.

Further, in FIG. 5 is a top view schematically illustrating a state in which a failure occurs in a particular vacuum processing chamber in the vacuum processing apparatus according to the embodiment shown in FIG. 1. Similar to FIG. 1, wafers are processed through the alternate processing. The figure shows a configuration of the apparatus in which four vacuum processing chambers are connected similar to the case of FIG. 1 but it is in a state that processings of a plurality of wafers have finished, no wafers have been transferred in to the four vacuum processing chambers, and the third vacuum processing chamber 105 is stopped due to some cause. When three sheets of wafers are to be transferred in this state, the control unit 150 controls based on the aforementioned operation flow such that the first water is transferred to the first vacuum processing chamber 103 first. After the wafer is transferred to the first vacuum processing chamber 103, the second wafer is so controlled as to be transferred to the second vacuum processing chamber 104. Then, the third wafer is transferred not to the third vacuum processing chamber 105 but to the fourth vacuum processing chamber 106.

With the above construction, in the vacuum processing apparatus 100, even in the event that a failure takes place in any vacuum processing chamber, the method for controlling the wafer transfer does not change essentially; the vacuum processing chamber for which a failure is detected is stopped and hermetically sectioned off from the other vessels of the vacuum-side block 102 and it is adjusted so that the first unprocessed wafer is transferred to a vacuum processing chamber which is to be transferred to next when the operation is resumed. Further, as in the embodiment described previously, by performing control such that wafers are transferred sequentially one by one to any one of the vacuum processing chambers in steady state except the vacuum processing chamber of the failed state connected to the respective vacuum transfer chambers from the first vacuum transfer chamber arranged in front close to the cabinet 109 toward the backmost vacuum transfer chamber and the processings are started, it becomes possible to distribute transfer loads imposed upon the respective vacuum transfer robots arranged in the vacuum transfer chambers and to improve the production efficiency of the overall apparatus.

According to the embodiments set forth so far, a semiconductor manufacturing apparatus having high productivity per unit footprint can be provided.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus comprising:
a plurality of vacuum transfer chambers being arranged behind an atmospheric transfer chamber, being coupled mutually, and having vacuum transfer robots located in their decompressed interior to transfer a wafer;
a plurality of vacuum processing chambers, at least one of the vacuum processing chambers being coupled to each of the vacuum transfer chambers, a plurality of wafers in a cassette arranged in front of the atmospheric transfer chamber being taken out of the cassette, being transferred successively to the plurality of the vacuum processing chambers by the vacuum transfer robots to be processed, and being returned to the cassette afterwards; and
a control unit setting operation of transfer of the plurality of the wafers and controlling the operation, the control unit controlling such that arbitrary ones of the plurality of the wafers are transferred to all of the vacuum processing chambers coupled to one arranged backmost out of the plurality of the vacuum transfer chambers and consequently controlling such that a next wafer is transferred to one of the plurality of the vacuum processing chambers possible for the next wafer to be transferred in before the arbitrary wafers become possible to be transferred out from the vacuum processing chambers coupled to the backmost vacuum transfer chamber and arranged backmost.

2. The vacuum processing apparatus according to claim 1, wherein the control unit controls such that the next wafer is transferred to a vacuum processing chamber coupled to a backmost vacuum transfer chamber among the plurality of the vacuum processing chambers coupled to the vacuum transfer chambers arranged forward with respect to the backmost vacuum transfer chamber.

3. The vacuum processing apparatus according to claim 1 further comprising:
an intermediate chamber arranged between adjacent ones of the plurality of the vacuum transfer chambers so as to couple them and capable of storing a plurality of the wafers in its interior communicated with the plurality of the vacuum transfer chambers; and
at least one lock chamber arranged between a vacuum transfer chamber arranged frontmost out of the plurality of the vacuum transfer chambers and the atmospheric transfer chamber so as to couple them;
wherein regarding transfers of the wafers by the vacuum transfer robots time required for transfer between the vacuum processing chamber and either the intermediate chamber or the lock chamber is longer than time required for transfer between the intermediate chamber or the lock chamber.

4. The vacuum processing apparatus according to claim 2 further comprising:
an intermediate chamber arranged between adjacent ones of the plurality of the vacuum transfer chambers so as to couple them and capable of storing a plurality of the wafers in its interior communicated with the plurality of the vacuum transfer chambers; and
at least one lock chamber arranged between a vacuum transfer chamber arranged frontmost out of the plurality of the vacuum transfer chambers and the atmospheric transfer chamber so as to couple them;
wherein regarding transfers of the wafers by the vacuum transfer robots time required for transfer between the vacuum processing chamber and either the intermediate chamber or the lock chamber is longer than time required for transfer between the intermediate chamber or the lock chamber.

5. The vacuum processing apparatus according to claim 1 further comprising:
an intermediate chamber arranged between adjacent ones of the plurality of the vacuum transfer chambers so as to couple them and capable of storing a plurality of the wafers in its interior communicated with the plurality of the vacuum transfer chamber, and
at least one lock chamber arranged between a vacuum transfer chamber arranged frontmost out of the plurality of the vacuum transfer chambers and the atmospheric transfer chamber so as to couple them and capable of storing the wafer in its interior;
wherein each of the plurality of the vacuum processing chambers comprises in its interior a sample stage on a top surface of which the wafer is mounted and held, the sample stage comprising:
a plurality of pins arranged internally, moving up and down, and holding the wafer on their tips while the tips are moved up above the top surface; and
a film made of dielectric material constituting the top surface and adhering and holding the wafer by a generated electrostatic force while the wafer is mounted thereon; and
wherein each of the intermediate chamber and the lock chamber comprises internally a fixed holding portion on which the wafer is mounted and held.

6. The vacuum processing apparatus according to claim 2 further comprising:
an intermediate chamber arranged between adjacent ones of the plurality of the vacuum transfer chambers so as to couple them and capable of storing a plurality of the wafers in its interior communicated with the plurality of the vacuum transfer chamber, and
at least one lock chamber arranged between a vacuum transfer chamber arranged frontmost out of the plurality of the vacuum transfer chambers and the atmospheric transfer chamber so as to couple them and capable of storing the wafer in its interior;
wherein each of the plurality of the vacuum processing chambers comprises in its interior a sample stage on a top surface of which the wafer is mounted and held, the sample stage comprising:
a plurality of pins arranged internally, moving up and down, and holding the wafer on their tips while the tips are moved up above the top surface; and
a film made of dielectric material constituting the top surface and adhering and holding the wafer by a generated electrostatic force while the wafer is mounted thereon; and
wherein each of the intermediate chamber and the lock chamber comprises internally a fixed holding portion on which the wafer is mounted and held.

7. The vacuum processing apparatus according to claim 1, wherein transfer of the next wafer is adjusted such that the wafers are transferred one by one to each of the vacuum processing chambers coupled to each of the plurality of the vacuum transfer chambers from the frontmost vacuum transfer chamber to back vacuum transfer chambers, the wafers are transferred to all of the vacuum processing chambers coupled to the backmost vacuum transfer chamber, and thereafter the next wafer is transferred to the vacuum processing chamber possible for the next wafer to be transferred in before the wafers, which are transferred to the vacuum processing chambers coupled to the backmost vacuum transfer chamber, become possible to be transferred out from the vacuum processing chambers and arranged backmost.

8. The vacuum processing apparatus according to claim 2, wherein transfer of the next wafer is adjusted such that the wafers are transferred one by one to each of the vacuum processing chambers coupled to each of the plurality of the vacuum transfer chambers from the frontmost vacuum transfer chamber to back vacuum transfer chambers, the wafers are transferred to all of the vacuum processing chambers coupled to the backmost vacuum transfer chamber, and thereafter the next wafer is transferred to the vacuum processing chamber possible for the next wafer to be transferred in before the wafers, which are transferred to the vacuum processing chambers coupled to the backmost vacuum transfer chamber, become possible to be transferred out from the vacuum processing chambers and arranged backmost.

9. A vacuum processing apparatus comprising:
a plurality of vacuum transfer chambers being arranged behind an atmospheric transfer chamber, being coupled mutually, and having vacuum transfer robots located in their decompressed interior to transfer a wafer;
a plurality of vacuum processing chambers, at least one of the vacuum processing chambers being coupled to each of the vacuum transfer chambers, a plurality of wafers in a plurality of cassettes mounted on a plurality of cassette stands arranged in front of the atmospheric transfer chamber being taken out of the cassettes, being transferred successively to the plurality of the vacuum processing chambers associated with the cassettes by said vacuum transfer robots to be processed, and being returned to the cassettes afterward; and
a control unit setting operation of transfers of the plurality of the wafers and controlling the operation, the control unit controlling such that wafers are taken out successively one by one out of each of the plurality of the cassettes and are transferred one by one to each of the vacuum processing chambers coupled to each of the plurality of the vacuum transfer chambers from the frontmost vacuum transfer chamber to the backmost vacuum transfer chamber, the wafers are transferred to all of the vacuum processing chambers coupled to the backmost vacuum transfer chamber, and thereafter the wafers are transferred to each of the vacuum processing chambers coupled to each of the vacuum transfer chambers up to the frontmost vacuum transfer chamber.
